(19) United States
(12) Patent Application Publication
(10) Pub. No.: US 2007/0013053 A1
(43) Pub. Date: Jan. 18, 2007

(54) Semiconductor device and method for manufacturing a semiconductor device

(76) Inventors: Peter Chou, Taipei (TW); Bear Zhang, Tianjin (CN)

Correspondence Address: MAYER & WILLIAMS PC, 251 NORTH AVENUE WEST, 2ND FLOOR, WESTFIELD, NJ, 07090, US

(21) Appl. No.: 11/179,334

(22) Filed: Jul. 12, 2005

(51) Int. Cl. H01L 23/34

(52) U.S. Cl. 257/706; 257/718; 257/E23.051

(57) ABSTRACT

A semiconductor device mountable to a substrate includes: a semiconductor die; an electrically conductive attachment region having a first attachment surface and a second attachment surface, the first attachment surface arranged for electrical communication with the semiconductor die; an interface material having a first interface surface and a second interface surface, the first interface surface in contact with the second attachment surface of the electrically conductive attachment region; a thermally conductive element in contact with the second interface surface; and a housing at least in part enclosing the semiconductor die and affixed to the thermally conductive element. The thermally conductive element and the housing form exterior packaging of the semiconductor device. Heat is removable from the semiconductor die to the exterior packaging via a thermal conduction path formed by the electrically conductive attachment region, the interface material, and the thermally conductive element.

### BACKGROUND

Aspects of this invention relate generally to a semiconductor device and to a method for manufacturing a semiconductor device, and more particularly to a semiconductor device having a heat sink forming a portion of the exterior packaging thereof, and to a method of manufacturing the semiconductor device.

A major cause of reduced efficiency in semiconductor devices such as rectifiers is inadequate cooling during normal operation. FIG. 1 is a perspective view of a Vishay® Semiconductor brand single phase inline bridge rectifier device 10 having four semiconductor die inside (not shown), manufactured by Vishay Intertechnology, Inc. Device 10 is through-hole mountable via leads 14, and includes an exterior epoxy housing 12 that protects the semiconductor dies—during operation of device 10, heat generated by the semiconductor dies is transferred through leads 14 and housing 12. FIG. 1B is a side view of device 10, illustrating the through-hole mounting thereof to a substrate 11 (a circuit board, for example), and further illustrating how a heat sink (such as a finned aluminum plate) 13 may be used to increase the thermal dissipation performance of housing 12—heat generated by dies within housing 12 is transferred to substrate 11 via leads 14, and through housing 12 to heat sink 13 and/or the ambient environment. Device 10, substrate 11, and heat sink 13 are cooled using a cooling technique such as natural or forced-air convection. The thermal conductivity of epoxy housing 12 is much less than that of heat sink 13, however, which often results in device 10 having poor thermal dissipation performance.

Semiconductor device package designs that incorporate additional cooling features have been proposed. International Rectifier Corporation, for example, has created a surface-mountable metal oxide semiconductor field effect transistor (“MOSFET”) chip set referred to as DirectFET™. Certain DirectFET™ devices have a copper can construction, which is advertised to enable dual-side cooling. U.S. Pat. No. 6,624,522 (the “'522 Patent”) and U.S. Pat. No. 6,784,540 (the “'540 Patent”) describe certain aspects of the construction and/or manufacture of surface-mountable semiconductor devices such as DirectFET™ devices.

The '522 Patent and the '540 Patent disclose, among other things, a conductive die clip (which may include other heat dissipation structures) that forms the copper can packaging. The die clip acts as a heat sink for a surface-mountable die, dissipating heat away from the circuit board during normal operation. The copper can, however, is not electrically isolated—mounting to an external heat sink requires the use of an isolation element (a ceramic or rubber isolation plate, or isolation an grease, for example), which adds additional cost and configuration complexity. The copper can may also add weight and expense to the device over what the use of other metals, such as aluminum, would add.

There is therefore a need for a semiconductor device (and a method of manufacturing therefor), which has a package design incorporating an electrically isolated, lightweight, inexpensive heat sink that can be used in both surface-mountable and through-hole-mountable applications to provide for significant heat removal from the semiconductor device, in some instances through a path other than into the substrate upon which the semiconductor device is mountable.

### SUMMARY

According to one aspect of the present invention, a semiconductor device mountable to a substrate includes: a semiconductor die; an electrically conductive attachment region (such as a copper pad, a solder ball, a lead, a lead frame, or a lead frame terminal) having a first attachment surface and a second attachment surface, the first attachment surface arranged for electrical communication with the semiconductor die; an interface material (a dielectric thermally conductive material such as a grease, an elastomeric pad, a thermal tape, a fluid, a gel, or an adhesive, for example) having a first interface surface and a second interface surface, the first interface surface in contact with the second attachment surface of the electrically conductive attachment region; a thermally conductive element (an metal plate, such as an aluminum plate) in contact with the second interface surface; and a housing (such as a molding compound) at least in part enclosing the semiconductor die and affixed to the thermally conductive element. The thermally conductive element and the housing are arranged (by molding for example) to form exterior packaging of the semiconductor device. Heat is removable from the semiconductor die to the exterior packaging of the semiconductor device via a thermal conduction path formed by the electrically conductive attachment region, the interface material, and the thermally conductive element.

The semiconductor device may be a power semiconductor device, such as a rectifier (a bridge rectifier, for example), or an integrated circuit (a chip-scale package, for example), and may be either surface- or through-hole-mountable. The thermally conductive element and the interface material compose a heat sink, and the heat sink is electrically isolated from the electrically conductive attachment region. The thermal conduction path may remove heat from the semiconductor die in a direction not toward the substrate to which the semiconductor device is mountable.

According to another aspect of the present invention, a method of manufacturing a semiconductor device mountable to a substrate includes: arranging a semiconductor die for electrical communication with a first attachment area of an electrically conductive attachment region; providing a heat sink, the heat sink including an interface material having a first interface surface and a second interface surface, and a thermally conductive element in contact with the second interface surface of the interface material; arranging for contact between a second attachment area of the electrically conductive attachment region and the first interface surface of the interface material, the first interface surface at least in part electrically isolating the electrically conductive attachment region and the thermally conductive element; and providing a housing at least in part enclosing the die, the housing affixed to the heat sink in such a manner that exterior packaging of the semiconductor device is provided by the housing and the thermally conductive element of the heat sink, heat removable from the semiconductor die to the exterior packaging of the semiconductor device via a thermal conduction path formed by the electrically conductive attachment region and the heat sink.

The method may further include molding the housing to the heat sink to form the exterior packaging of the semiconductor device.

### BRIEF DESCRIPTION OF THE DRAWINGS

FIG. 1A is a perspective view of general packaging for a through-hole mountable semiconductor device.

FIG. 1B is a side view of the semiconductor device shown in FIG. 1, through-hole mounted to a circuit board.

FIG. 2 is a perspective view of a heat sink design usable to form exterior packaging of a semiconductor device in accordance with aspects of the present invention.

FIG. 3 is a side view, in direction of arrows 3-3, of the heat sink shown in FIG. 2.

FIG. 4 is a side view of an interior cross-section of a through-hole-mountable semiconductor device for which the heat sink shown in FIG. 2 forms exterior packaging thereof, in accordance with certain aspects of the present invention. FIG. 5 is a plan view, in direction of arrows 5-5, of the semiconductor device shown in FIG. 4.

FIG. 6 is a side view, in direction of arrows 6-6, of the semiconductor device shown in FIG. 5.

FIG. 7 is a side view of an interior cross-section of another through-hole-mountable semiconductor device for which the heat sink shown in FIG. 2 forms exterior packaging thereof, in accordance with certain other aspects of the present invention.

FIG. 8 is a bottom plan view, in direction of arrows 8-8, of the semiconductor device shown in FIG. 7.

FIG. 9 is a top plan view, in direction of arrows 9-9, of the semiconductor device shown in FIG. 7.

FIG. 10 is a side view, in direction of arrows 10-10, of the semiconductor device shown in FIG. 9.

FIG. 11 is a diagram illustrating certain thermal conduction paths through which heat is removed from the semiconductor device shown in FIG. 4 (which has been rotated 90 degrees in direction of arrow 7) during normal operation of the semiconductor device.

FIG. 12 is a side view of an interior cross-section of a surface-mountable semiconductor device for which a heat sink forms exterior packaging thereof, in accordance with other aspects of the present invention.

FIG. 13 is a bottom exterior view of another surface-mountable semiconductor device for which a heat sink forms exterior packaging thereof, in accordance with further aspects of the present invention.

FIG. 14 is a top exterior view of the surface-mountable semiconductor device shown in FIG. 13.

FIG. 15 is a flowchart of a method for manufacturing a semiconductor device in accordance with aspects of the present invention.

### DETAILED DESCRIPTION

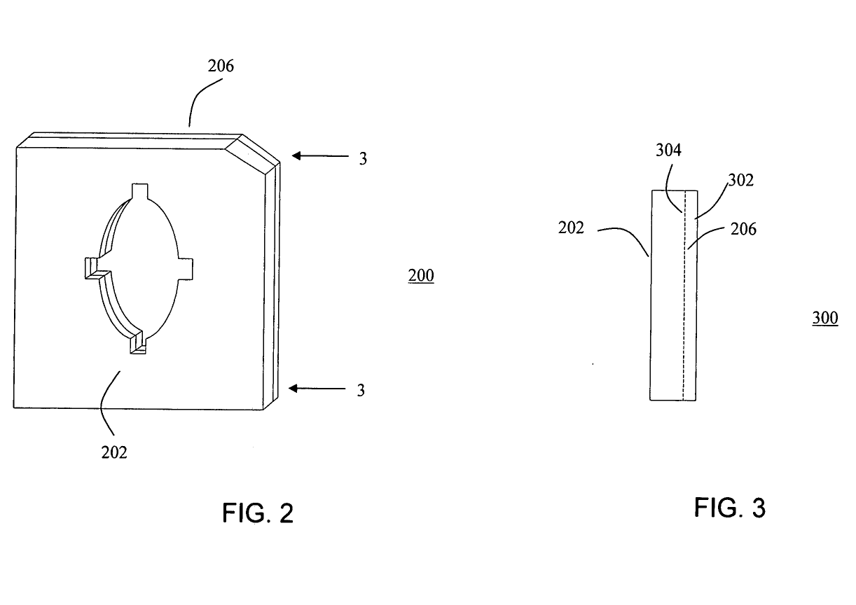

Turning now to the drawings, where like numerals designate like components, FIG. 2 is a plan view of a heat sink design 200 usable to form exterior packaging of a semiconductor device in accordance with aspects of the present invention. Heat sink design 200 includes a thermally conductive element 202 and an interface material 206.

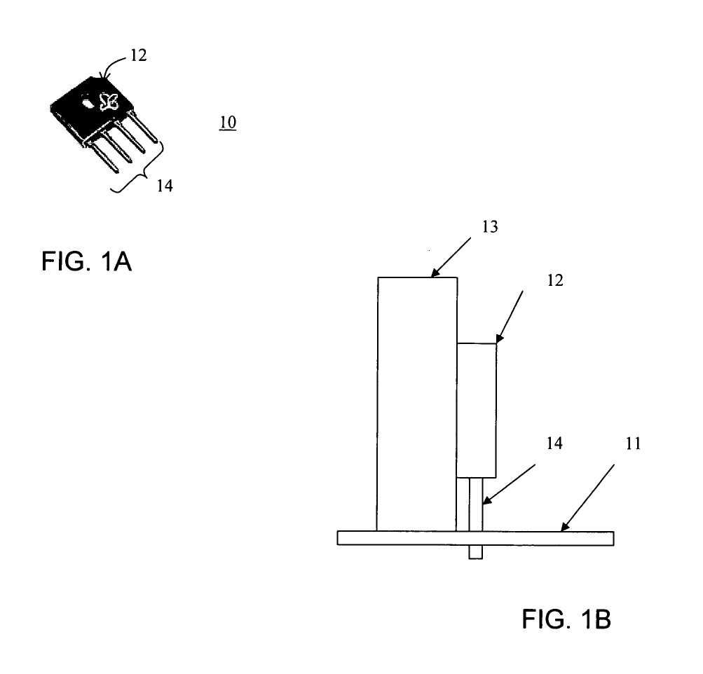

As discussed further below, thermally conductive element 202 forms at least a portion of the exterior packaging of a semiconductor device. Thermally conductive element 202 may be made of a metal, such as aluminum, which is relatively lightweight, inexpensive, easily manufactured and has a high thermal conductivity, or made of another material now known or later developed, such as copper, brass, steel, ceramics, or metalized plastic. Thermally conductive element 202 may be formed in any desired configuration/shape by a variety of well-known methods such as casting and machining, among others. As shown, thermally conductive element 202 is a substantially rectangular aluminum plate approximately 0.8 mm thick (although it may be thinner or thicker) having a hole 208 therein, designed for compatibility with exterior housing 12 of the semiconductor device shown in FIG. 1.

Interface material 206 is a dielectric thermally conductive material, which functions to minimize thermally insulating gaps between interface material 206 and thermally conductive element 202 while maximizing heat dissipation through thermally conductive element 202, and to provide electrical isolation between a semiconductor device and thermally conductive element 202. Interface material 206 may be a grease, an elastomeric pad, a thermal tape, a fluid, a gel, an adhesive, or any other thermal interface material now know or later developed. As shown, interface material 206 has a configuration/shape generally similar to that of thermally conductive element 202, although interface material 206 may be formed in any desired configuration/shape. As shown, interface material 206 is a layer of fiberglass rubber with double-sided pressure-sensitive adhesive tape having a thickness of approximately 0.1 mm having a hole (not shown) therein, designed for compatibility with exterior housing 12 of the semiconductor device shown in FIG. 1.

As shown in FIG. 3, which is a side view, in direction 3-3, of heat sink 200 (shown in FIG. 2), interface material 206 has two surfaces 302 and 304—a first side 302 and a second side 304. The shapes and/or configurations of surfaces 302 and 304 may, however, vary according to the shape and/or configuration of interface material 206. As discussed further below, first side 302 is configured for contact with an electrically conductive region associated with a semiconductor device. Second side 304 is affixed to thermally conductive element 202 in any manner suitable to the selected material that minimizes thermally insulating gaps between interface material 206 and thermally conductive element 202. For example, second side 304 may be a double-sided pressure-sensitive adhesive tape that bonds interface material 206 to thermally conductive element 202.

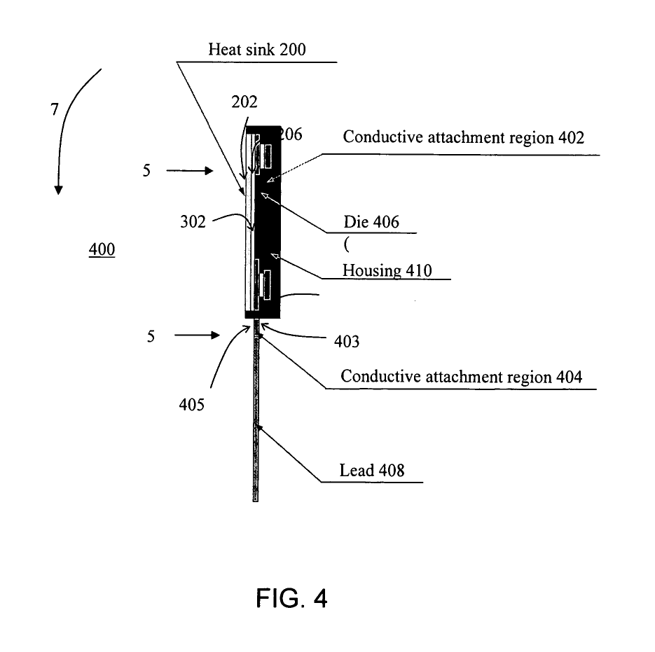

FIG. 4 is a side view of an interior cross-section of a through-hole mountable semiconductor device 400 for which the heat sink shown in FIG. 2 forms exterior packaging thereof, in accordance with certain aspects of the present invention. For exemplary purposes, semiconductor device 400 has a similar footprint and die arrangement (device 400 includes four die, two are visible in FIG. 4) as through-hole mountable semiconductor device 10 (shown in FIG. 1), although device 400 may have different exterior dimensions or geometries altogether. Semiconductor device 400 may be a power semiconductor device, such as a rectifier or another type of integrated circuit.

Electrically conductive attachment regions 404, such as a copper pads, solder balls, leads, lead frames, or lead frame terminals, each have one surface 403 arranged to provide electrical communication with a semiconductor die 406 (two die are visible, although only one die is referenced for exemplary purposes.) Die 406 may be, for example, a diode, a MOSFET, or another type of die/integrated circuit. Surface 403 may be attached to die 406 in any suitable manner, such as by soldering. Through-hole mountable leads 408 (one visible) may also be in electrical communication with semiconductor die 406 and/or electrically conductive attachment region 404. Another surface 405 of electrically conductive attachment region 404 is in contact with first side 302 of interface material 206 by suitable pressure for adhesion.

A housing 410 at least in part encloses die 406 and is affixed to thermally conductive element 202 and/or interface material 206—the housing and the thermally conductive element are arranged to form exterior packaging of semiconductor device 400. Housing 410 may be a molding compound, such as a plastic, molded to thermally conductive element 202 and/or interface material 206. Housing 410 may be formed in any desired configuration/shape by a variety of well-known methods, such as overmolding or eject molding. As shown, housing 410 is approximately 3.5 mm thick with a configuration similar to portions of exterior housing 12 of semiconductor device 10 (shown in FIG. 1).

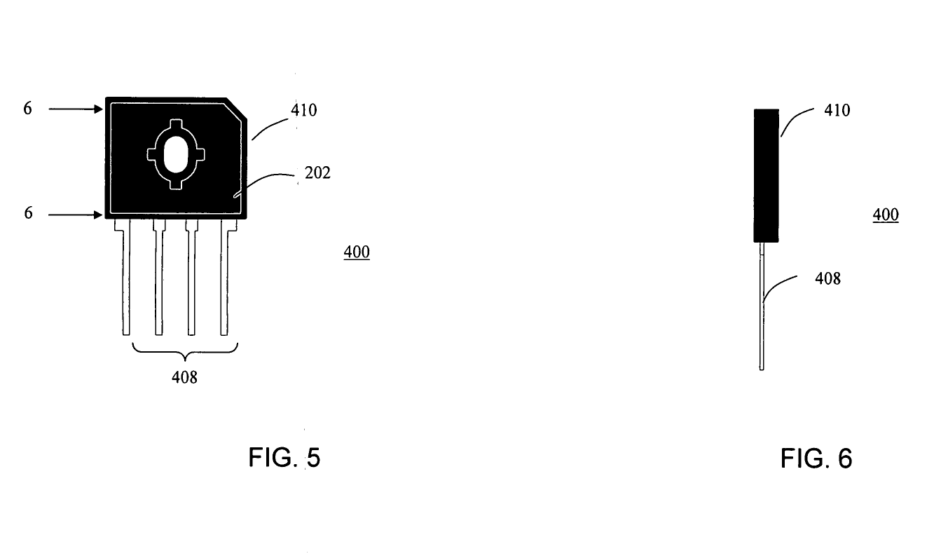

FIG. 5 is a plan view, in direction of arrows 5-5, of semiconductor device 400 (shown in FIG. 4.) In accordance with certain aspects of the present invention, thermally conductive element 202 is arranged with housing 410 to form exterior packaging of semiconductor device 400. Exterior packaging of semiconductor device 400 is further depicted in FIG. 6, which is a side view, in direction of arrows 6-6, of semiconductor device 400 (shown in FIG. 5.)

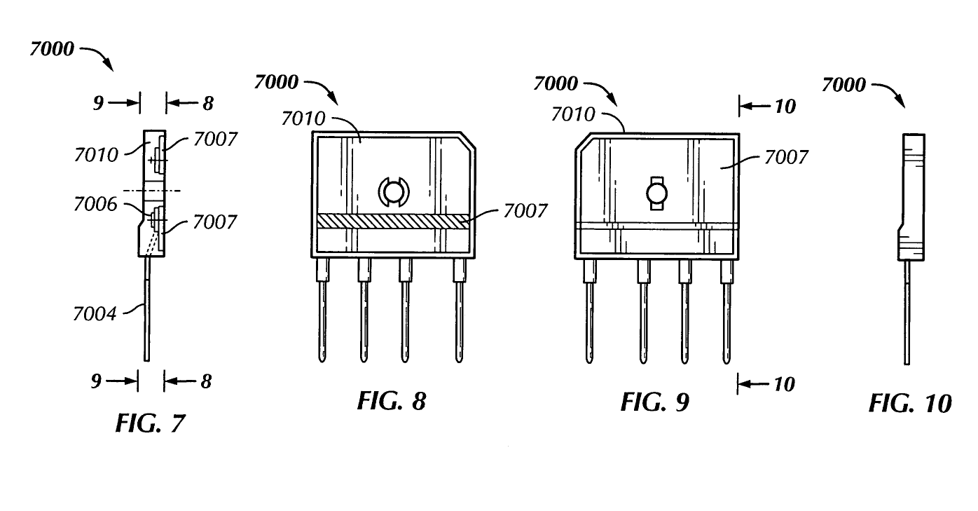

FIG. 7 is a side view of an interior cross-section of another through-hole-mountable semiconductor device 7000 (such as a power semiconductor device, such as a rectifier or another type of integrated circuit) for which a heat sink having elements shown in FIG. 2 forms exterior packaging thereof, in accordance with certain other aspects of the present invention. Electrically conductive attachment regions 7004 (one visible), such as copper pads, solder ails, leads, lead frames, or lead frame terminals, each have surfaces arranged to provide electrical communication with one or more semiconductor die 7006. Electrically conductive attachment region 7004 is also in contact with heat sink 7007, which includes an interface material portion (such as interface material 206) and a thermally conductive element (such as thermally conductive element 202). A housing compound 7010, such as a molded plastic compound, at least in part encloses die 7006 and is affixed to the thermally conductive element and/or interface material of heat sink 7007.

FIG. 8 is a bottom plan view, in direction of arrows 8-8, of the semiconductor device shown in FIG. 7. Heat sink 7007 is arranged with housing 7010 to form exterior packaging of semiconductor device 7000.

FIG. 9 is a top plan view, in direction of arrows 9-9, of the semiconductor device shown in FIG. 7. It can be seen that housing 7010 is configured in a manner such that a portion of heat sink 7007 is visible through housing 7010, for addition thermal conduction. Exterior packaging of semiconductor device 7000 is further depicted in FIG. 10, which is a side view, in direction of arrows 10-10, of semiconductor 7000 (as shown in FIG. 9).

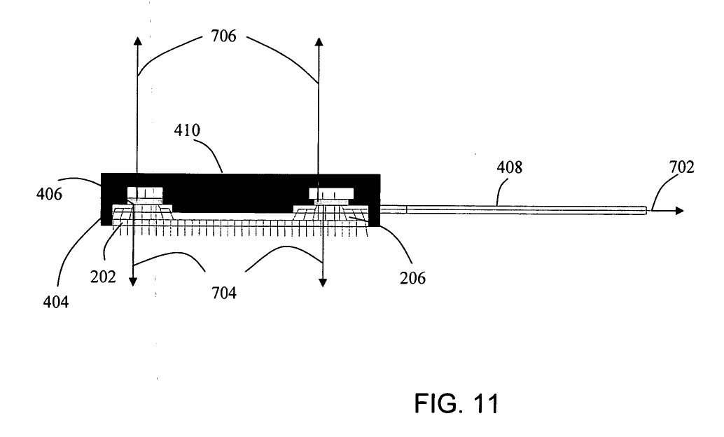

FIG. 11 is a diagram illustrating thermal conduction paths through which heat is removed from semiconductor device 400 (shown in FIG. 4, rotated 90 degrees in direction of arrow 7) during normal operation. As shown, heat is transferred from die 406 along a path depicted by arrow 702, through leads 408 (one visible) and into a substrate (not shown) to which leads 408 are mountable, and from die 406 along a path depicted by arrows 706, through housing 410 to the ambient environment. Heat is also transferred in significant amounts along another path, depicted by arrows 704, from die 406 through conductive attachment region 404, interface material 206, and thermally conductive element 202 (and further to an external heat sink in certain applications), in directions not toward the substrate to which leads 408 would be mounted.

Thus semiconductor devices have been described that include significant heat removal paths created by contact between a semiconductor die and an electrically isolated heat sink (which may be lightweight and inexpensive—aluminum, for example). Conducting heat away from mounting substrates is desirable in product designs that feature increased component densities, and thus increased heat flux densities, on each substrate—cooling provided for the substrate, which generally results in a single operating temperature being provided for a relatively large surface area, is supplemented by the electrically isolated semiconductor device package itself. Semiconductor devices may operate at more desirable temperatures without significant alterations in their footprints, and/or without additional isolation requirements, reducing the need for product re-designs.

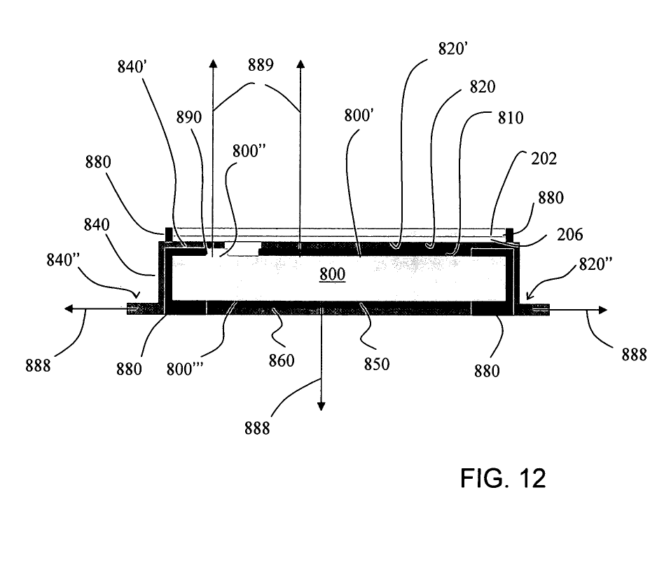

Aspects of the present invention described above with respect to through-hole mountable semiconductor devices are also applicable to surface-mountable semiconductor devices. FIG. 12 is a front view of an interior cross-section of a surface-mountable semiconductor device (a chip-scale device, for example) for which a heat sink (such as the heat sink formed by thermally conductive element 202 and interface material 206 shown in FIG. 2, configured in a manner suitable for the footprint of the semiconductor device shown in FIG. 12) forms exterior packaging thereof, in accordance with other aspects of the present invention.

As shown, a MOSFET die 800 includes a gate 800″, a source 800′, and a drain 800′″. A first lead frame 820 has a first terminal 820′ and a second terminal 820″. First terminal 820′ is connected to source 800′ through a solder 810. A second lead frame 840 also has a first terminal 840′ and a second terminal 840″. First terminal 840′ is connected to gate 800″ through a silver paste 890. An electrically conductive plate (for example, a copper plate) 860 is connected to drain 800′″ through a solder 850. A packaging material 880 is used to encapsulate die 800, first terminals 820′ and 840′ of first and second lead frames 820 and 840, respectively, silver paste 890, solder 810, 830, and 850, and at least a portion of thermally conductive element 202 and/or interface material 206.

A thermal conduction path allows heat to be transferred from die 800 (drain 800′″, gate 800″ and/or source 800′) in directions 888 toward a substrate (not shown) to which the semiconductor device is mountable. Heat is also transferred in significant amounts via another thermal conduction path in a direction (not toward the substrate to which the semiconductor device would be mounted) depicted by arrows 889, from die 800 through conductive attachment regions such as first and second lead frames 820 and 840 (and/or first terminals 820′ and 840′ thereof), interface material 206, and thermally conductive element 202.

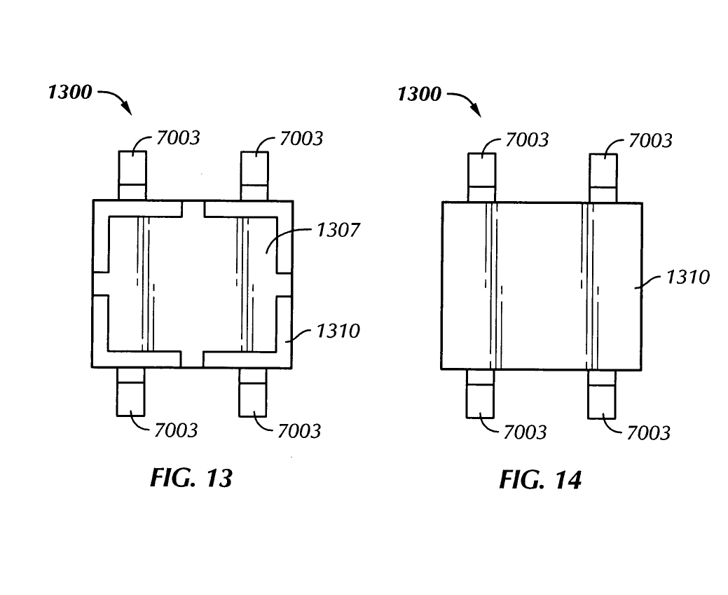

FIG. 13 is a bottom exterior view of another surface-mountable semiconductor device 1300 for which a heat sink 1307 and a housing 1310, such as a molding compound, forms exterior packaging thereof, in accordance with further aspects of the present invention. Heat sink 1307 may be a the heat sink formed by thermally conductive element 202 and interface material 206, as shown in FIG. 2, and configured to be compatible with the footprint of semiconductor device 1300. Heat is directed in a direction toward a substrate (not shown) to which semiconductor device 1300 is mountable, via leads 7003 and heat sink 1307. A top exterior view of semiconductor device 1300, depicting configuration of housing 1310, is shown in FIG. 14.

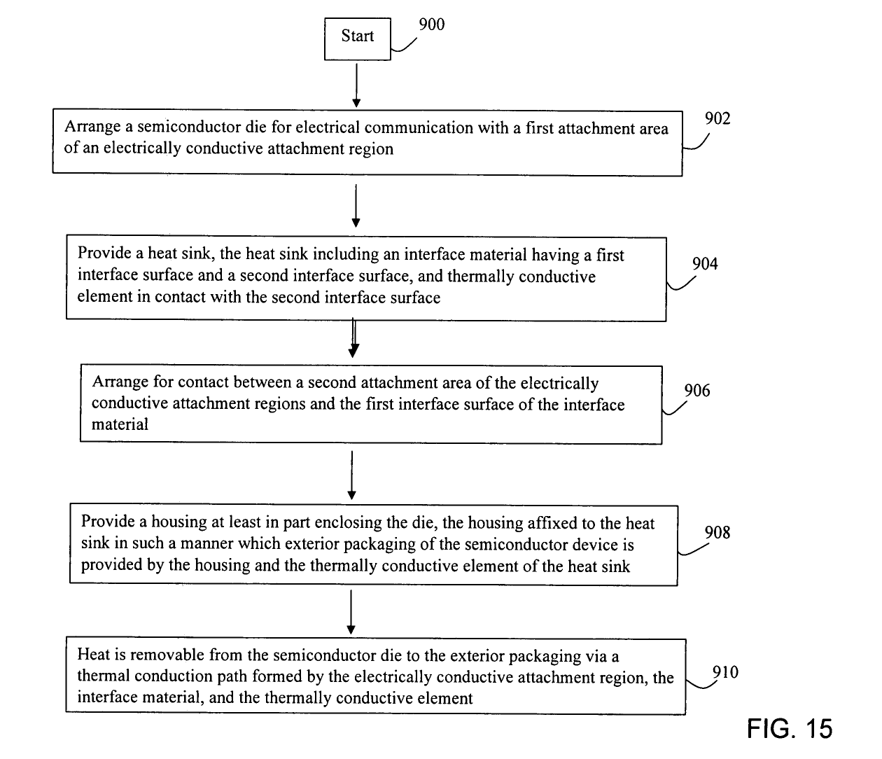

FIG. 15 is a flowchart of a method for manufacturing a semiconductor device, such as semiconductor device 400 shown in FIG. 4, the semiconductor device 7000 shown in FIG. 7, the semiconductor device 800 shown in FIG. 12, or the semiconductor device 1300 shown in FIG. 13, in accordance with aspects of the present invention. The method begins at block 900, and continues at block 902, where a semiconductor die is arranged for electrical communication with a first attachment area of an electrically conductive attachment region, such as a copper pad, a lead frame, or a terminal thereof.

Next, at block 904, a heat sink is provided. The heat sink includes an interface material, such as interface material 206, which has a first interface surface and a second interface surface. The heat sink also includes a thermally conductive element, such as thermally conductive element 202, in contact with the second interface surface of the interface material.

At block 906, it is arranged for contact to be made between the first interface surface of the interface material and a second attachment area of the electrically conductive attachment region.

At block 908, a housing, which may be composed of a material such as plastic, is provided that at least in part encloses the die. The housing is affixed (by molding, for example) to the heat sink in such a manner that exterior packaging of the semiconductor device is provided by the housing and the thermally conductive element of the heat sink. As illustrated by block 910, heat is removable from the semiconductor die to the exterior packaging of the semiconductor device via a thermal conduction path formed by the electrically conductive attachment region, the interface material, and the thermally conductive element.

Thus, through-hole- and surface-mountable semiconductor devices and manufacturing method(s) therefor have been described, which have package designs incorporating a lightweight, inexpensive, electrically isolated heat sink that may be made to conform to a variety of device footprints to oftentimes provide significant heat removal through a path other than toward the substrate upon which the semiconductor device is mountable.

It will be apparent that other and further forms of the aspects of the present invention described herein may be devised without departing from the spirit and scope of the appended claims, and it will be understood that aspects of this invention are not to be limited to the specific embodiments described above.

1. A semiconductor device mountable to a substrate, comprising:
a semiconductor die;
an electrically conductive attachment region having a first attachment surface and a second attachment surface, the first attachment surface arranged for electrical communication with the semiconductor die;
an interface material having a first interface surface and a second interface surface, the first interface surface in contact with the second attachment surface of the electrically conductive attachment region;
a thermally conductive element in contact with the second interface surface; and
a housing at least in part enclosing the semiconductor die and affixed to the thermally conductive element,
the thermally conductive element and the housing arranged to form exterior packaging of the semiconductor device, heat removable from the semiconductor die to the exterior packaging of the semiconductor device via a thermal conduction path formed by the electrically conductive attachment region, the interface material, and the thermally conductive element.

2. The semiconductor device according to claim 1, wherein the semiconductor device comprises a power semiconductor device.

3. The semiconductor device according to claim 2, wherein the power semiconductor device comprises a rectifier.

4. The semiconductor device according to claim 3, wherein the rectifier comprises a bridge rectifier.

5. The semiconductor device according to claim 1, wherein the semiconductor device comprises a surface-mountable device.

6. The semiconductor device according to claim 1, wherein the semiconductor device comprises a through-hole-mountable device.

7. The semiconductor device according to claim 1, wherein the semiconductor device comprises an integrated circuit.

8. The semiconductor device according to claim 7, wherein the integrated circuit comprises a chip-scale package.

9. The semiconductor device according to claim 8, wherein the electrically conductive attachment region comprises one of a copper pad, a solder ball, a lead, a lead frame, and a lead frame terminal.

10. The semiconductor device according to claim 9, wherein the interface material comprises a dielectric thermally conductive material.

11. The semiconductor device according to claim 10, wherein the dielectric thermally-conductive material comprises one of a grease, an elastomeric pad, a thermal tape, a fluid, a gel, and an adhesive.

12. The semiconductor device according to claim 10, wherein the thermally conductive element comprises a metal plate.

13. The semiconductor device according to claim 12, wherein the metal plate comprises an aluminum plate.

14. The semiconductor device according to claim 12, wherein the metal plate and the dielectric thermally conductive interface material comprise a heat sink, the heat sink electrically isolated from the electrically conductive attachment region.

15. The semiconductor device according to claim 14, wherein heat is removable from the semiconductor die, via the thermal conduction path, in a direction not toward the substrate to which the semiconductor device is mountable.

16. The semiconductor device according to claim 1, wherein the housing comprises a molding compound.

17. The semiconductor device according to claim 16, wherein the molding compound is molded to the heat sink to form exterior packaging of the semiconductor device.

18. A method of manufacturing a semiconductor device mountable to a substrate, the method comprising:
arranging a semiconductor die for electrical communication with a first attachment area of an electrically conductive attachment region;
providing a heat sink, the heat sink comprising
an interface material having a first interface surface and a second interface surface, and
a thermally conductive element in contact with the second interface surface of the interface material;
arranging for contact between a second attachment area of the electrically conductive attachment region and the first interface surface of the interface material, the first interface surface at least in part electrically isolating the electrically conductive attachment region and the thermally conductive element; and
providing a housing at least in part enclosing the die, the housing affixed to the heat sink in such a manner that exterior packaging of the semiconductor device is provided by the housing and the thermally conductive element of the heat sink, heat removable from the semiconductor die to the exterior packaging of the semiconductor device via a thermal conduction path formed by the electrically conductive attachment region and the heat sink.

19. The method of manufacturing the semiconductor device according to claim 18, further comprising:
molding the housing to the heat sink to form exterior packaging of the semiconductor device.

20. The method of manufacturing the semiconductor device according to claim 18, wherein heat is removable from the semiconductor die, via the thermal conduction path, in a direction not toward the substrate to which the semiconductor device is mountable.
